(19) United States
(12) Patent Application Publication
(10) Pub. No.: US 2025/0122444 A1
(43) Pub. Date: Apr. 17, 2025

(54) GRAPHENE COATED COMPONENTS FOR SUPERLUBRICITY

(71) Applicant: Worcester Polytechnic Institute, Worcester, MA (US)

(72) Inventors: Tabiri K. Asumadu, Worcester, MA (US); Mobin Vandadi, Worcester, MA (US); Kwadwo Mensah-Darkwa, Worcester, MA (US); Emmanuel Gikunoo, Worcester, MA (US); Samuel Kwofie, Worcester, MA (US); Desmond E.P. Klenam, Worcester, MA (US); Nima Rahbar, Weston, MA (US); Winston O. Soboyejo, Northborough, MA (US)

(21) Appl. No.: 18/634,107

(22) Filed: Apr. 12, 2024

Related U.S. Application Data
(60) Provisional application No. 63/458,954, filed on Apr. 13, 2023.
(60) Provisional application No. 63/458,955, filed on Apr. 13, 2023.
(60) Provisional application No. 63/458,956, filed on Apr. 13, 2023.

(51) Int. Cl. C10M 177/00; C10M 103/02; C10N 50/08; C10N 70/00; C23C 8/64

(52) U.S. Cl. CPC C10M 177/00; C10M 103/02; C23C 8/64; C10M 2201/0413; C10N 2050/08; C10N 2070/00

(57) ABSTRACT

A carbon coating such as graphene formed on an article or component forms a reduced friction surface on the component. The graphene forms a superlubricity coating for mitigating friction against engaged, moving surfaces. A metallic component receives a graphene coating resulting from a high temperature biowaste treatment (HTBT) by surrounding the metallic component with a granular biowaste medium defining a carbon source, and heating the metallic component in the biowaste medium for diffusing carbon from the biowaste medium to aggregate on a surface of the component, thereby forming a graphene coating.

### RELATED APPLICATIONS

This patent application claims the benefit under 35 U.S.C. § 119 (e) of U.S. Provisional Patent App. No. 63/458,954, filed Apr. 13, 2023, entitled “GRAPHENE COATED COMPONENTS FOR SUPERLUBRICITY;” U.S. Provisional Patent App. No. 63/458,955, filed Apr. 13, 2023, entitled “GRAPHENE DEPOSITION COATING;” and U.S. Provisional Patent App. No. 63/458,956, filed Apr. 13, 2023, entitled “BIOWASTE TREATMENT FOR SUPERLUBRICITY,” all incorporated herein by reference in entirety.

### BACKGROUND

Friction is a ubiquitous phenomenon across the engineering world. Globally, roughly 100 million terajoules of energy are required to reduce friction, accounting to a fifth of energy generated annually. About 1-4% of the Gross Domestic Product (GDP) of industrialized economies is spent on friction and wear phenomena. Lubricants, both petroleum/fossil based and synthetic, are a necessary component in any mechanical system. In passenger cars, for example, one-third of the fuel energy is used to overcome friction in the engine, transmission, tires, and brakes. Superlubricity is beneficial to the need to reduce energy losses associated with friction and wear phenomena in structural and functional components. Certain polymers may provide friction reduction, but often do not wear as well as metals.

### SUMMARY

A carbon coating such as graphene formed on an article or component forms a reduced friction surface on the component. The graphene forms a superlubricity coating for mitigating friction against engaged, moving surfaces. A metallic component receives a graphene coating resulting from a high temperature biowaste treatment (HTBT) by surrounding the metallic component with a granular biowaste medium defining a carbon source, and heating the metallic component in the granular biowaste medium for diffusing carbon from the biowaste medium to aggregate on a surface of the component thereby forming a graphene coating.

Configurations herein are based, in part, on the observation that interactions between metal parts rely on a lubricant for mitigating friction between moving components or parts. Fossil based lubricants, such as grease and oil, are often applied to junctures between moving parts to mitigate the friction between sliding metal surfaces. Superlubricity is a feature or characteristic formed in an article subject to friction, often through application of a coating for mitigation of the underlying friction. Unfortunately, conventional approaches to superlubricity coatings suffer from the shortcoming of expense and sophistication of the equipment needed. Conventional deposition techniques used for surface coatings include sputtering and chemical and physical vapor deposition (CVD/PVD) methods, which are expensive and not economically viable for large-scale depositions.

Accordingly, configurations herein substantially overcome the shortcomings of conventional superlubricity and friction-reducing coatings by depositing carbon nanocrystals with variants of graphene footprints on metallic surfaces using the HTBT process. This carbon/graphene coating results in ultralow (near-zero) friction of carbon-coated metallic depositions on substrates of structural steels, Ti, and Ni alloys. The macroscale superlubricity is sustained over several cycles through structural orientation exhibited by the carbon coating on the metallic surfaces.

In further detail, a method for forming superlubricity coating includes generating the granular biowaste medium from a carbon-bearing source, surrounding the metallic component with the granular biowaste medium for providing a carbon source, and heating the metallic component in the biowaste medium for diffusing carbon from the biowaste medium to aggregate on a surface of the component, thereby forming a graphene coating.

### BRIEF DESCRIPTION OF THE DRAWINGS

The foregoing and other objects, features and advantages of the invention will be apparent from the following description of particular embodiments of the invention, as illustrated in the accompanying drawings in which like reference characters refer to the same parts throughout the different views. The drawings are not necessarily to scale, emphasis instead being placed upon illustrating the principles of the invention.

FIG. 1 is a context diagram of a metal processing environment suitable for use with configurations herein;

FIG. 2 is a process flow for forming low friction coatings based on carbon crystals and carbon nanotubes;

FIGS. 3A and 3B show reference Raman shift spectra for identifying graphene coatings on metal articles;

FIG. 4 shows a Raman shift spectra for the superlubricity coating an example alloy;

FIGS. 5A-5C show surface roughness for the superlubricity coating;

FIGS. 6A-6D show SEM images of the superlubricity coating;

FIGS. 6E-6H show Raman shift graphs of the superlubricity coatings;

FIGS. 7A-7H depict surface features and graphs of Coefficient of Friction (CoF) attributes of the superlubricity coating; and

FIGS. 8A-8N show SEM images and Raman graphs of the graphene in the superlubricity coating.

### DETAILED DESCRIPTION

Configurations discussed below present a bioprocessing method for depositing superlubricious carbon coatings on metallic substrates. The disclosed approach relies on deposition of carbon nanocrystals and variants of graphene on bulk metallic substrates by extracting carbon from low-cost biowaste and plant sources. The biowaste derived coatings are deposited and oriented structurally to achieve macroscale superlubricity and/or frictionless conditions for sustained cycles. Substrates such as Complex Concentrated Alloys and High Entropy Alloys are particularly amenable to the disclosed coating process. However any suitable metallic substrate may be coated. The disclosed approach demonstrates scalable deposition of multi-layer graphene on Complex Concentrated Alloys/High Entropy Alloys for inducing superlubricity for structural and functional applications in technologies such as transportation, energy and manufacturing industries using low-cost HTBT.

Complex concentrated alloys (CCAs) and High Entropy Alloys (HEAs) are based on multiple principal elements with compositions in near equal atomic weights. These alloys extend the frontiers for alloy design beyond the conventional dilute alloying concentrations with potentially different properties for structural and functional applications. The excellent structural and functional properties are attributed to four core effects. The high entropy and enthalpy of mixing effect deviates from the Gibbs phase rule stabilizing phase proportions. This contributes to the observed properties, which are not common to most conventional one- or two-principal element-based materials. Most of these alloys undergo low kinetic transformation resulting in the sluggish diffusion effects. The effect of the interacting atoms due to size mismatch leads to the deformation of the crystal structure, resulting in the severe lattice distortion effects. There is a cocktail effect violating the rule-of-mixture from the indiscernible solute and solvent atoms, where the mechanical properties of the resulting CCAs are superior to the average constituent elements.

The concept of CCAs/HEAs was introduced in 2004. However active research and product development commenced in the late 2015 for monetizing a global outlook. The market forecast is expected to more than double by 2030, with a compound annual growth rate (CAGR) of ˜10.5%. This growth projections are due to increasing demand for mechanical components with strength-ductility synergies, high-strength, and lightweight materials for applications in automotive and aerospace applications, growing demand for energy-efficient materials and increasing investment in research, development, and innovation for new alloys. These alloys are gradually replacing one principal element-based alloys. This is attributed to the need for high performance gears and reduction in gearboxes for automotive. In the energy sector, an alternative for Ni-based superalloys, which have reached ˜90% of the melting temperature of Ni is being explored. Other applications include power transformers, wind turbine blades, motor magnets and semiconductors with higher thermal conductivity than SiC and GaN₂.

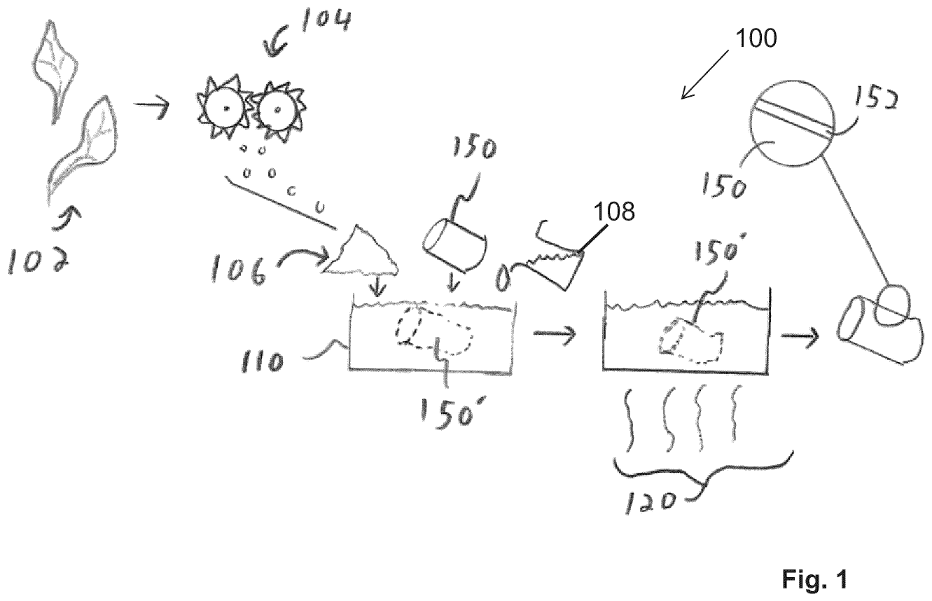

FIG. 1 is a context diagram of a metal processing environment suitable for use with configurations herein. Referring to FIG. 1, in the metal processing environment 100, a biowaste source 102 enters a grinding apparatus 104 to form a granular biowaste medium 106 of predetermined size particles. A metallic component 150 or article for coating is deposited in a containment 110 with the granular biowaste medium 106. An activation agent 108 may also be added, for facilitating introduction of nitrogen. The granular biowaste medium 106 may also include cyanide for favoring chemical reactions and carbon production.

The metallic component 150 is covered and surrounded by the biowaste particles 106 so that all surfaces of the submerged component 150′ are in contact with the granular biowaste medium 106. The containment 110 with the article 150′ is placed in an oven or furnace for heat treatment 120 at a predetermined temperature and duration, during which the carbon in the granular biowaste medium 106 diffuses into and coats the component 150′ to form a coating 152 of carbon crystals, carbon nanotubes and/or graphene components-crystalline forms of carbon contributing to superlubricity.

Carbon nanotubes (CNTs) can be single-walled, double-walled, triple-walled. Or multi-walled Single-walled CNTs have diameters of around 0.5-2.0 nanometers, for example.

Conventional approaches to biowaste sourced coatings rely on surface hardening and are limited to ferrous metals. The claimed approach, in contrast, works on a variety of alloys and forms a distinct layer of graphene or similar carbon based structure for superlubricity.

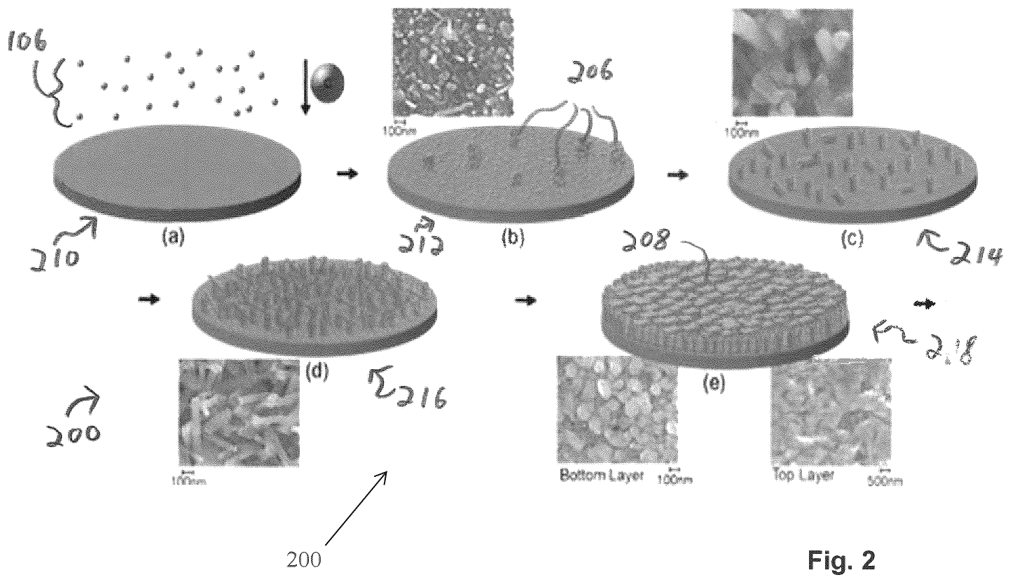

FIG. 2 is a process flow 200 for forming low friction coatings based on carbon crystals and carbon nanotubes. Referring to FIGS. 1 and 2. FIG. 2 depicts the deposition and diffusion of the carbon structures onto a substrate defined by the metallic component 150. Photographic examples accompany each step. HTBT was the technique used to deposit the carbon nanocrystal coatings. FIG. 2 shows multiple stages of in-situ deposition of the carbon coatings with microstructures. The stages of the in-situ coating deposition commences with the diffusion and saturation of carbon at around 900° C. into the substrate, as shown at step 210. The depth of diffusion and saturation is driven by the solubility of carbon in the substrate. After the saturation of the surface with carbon, crystals of carbon 206 precipitate and crystallize on the substrate, shown in step 212. The precipitated carbon crystals develop into nanotubes of various orientations, as shown at step 214. The substrate now exhibits nanocrystals with different vertical and horizontal orientations. These misaligned nanotubes resulting in the formation of forest-like features on the substrate, shown at step 216. The average diameter of the carbon crystals was estimated from the accompanying images to be 70±10 nm. The horizontal nanocrystals had an average length of 500±20 nm. The nanocrystals fuse at the walls to form a column base for the coating, after which patches of carbon nanocrystals form an upper plate-like layer or coating 208, as shown at step 218. The final carbon nanocrystals coating 208 is made up of misoriented patches and nanotubes, for various substrates such as Ni, CP Ti, Ti6Al4V and 1045 steel substrates.

FIG. 2 shows that carbon nanocrystals with signatures of graphene variants were deposited on bulk metallic substrates for providing a low friction or superlubricity coating. The granular biowaste medium may be provided by any suitable biowaste or plant matter having suitable carbon and nitrogen content. In the example configuration, the carbon source is derived from “Manihot esculenta” biowaste, commonly known as Casava leaves. This low-cost and sustainable approach fulfills the circular economic model-turning waste into usable raw materials. The technique is simple, easy to design, and less expensive than conventional CVD and PVD techniques currently used for carbon-based coatings. The structural orientation and morphology of the deposited carbon nanocrystals (CNC) and graphene variants lead to robust/sustained macroscale superlubricity on the bulk metallic surfaces for up to 150,000 cycles. The bioprocessing technique significantly reduced the friction coefficient and wear rates on commercially pure (CP) Ti, Ti-6Al-4V, Ni-Invar, and structural steel (AISI 1045) substrates.

Superlubricity can be measured according to a coefficient of friction (CoF), which also varies according to the underlying alloy upon which the superlubricity coating is applied. In the case of titanium-based alloys, for example, the CoF of the treated Ti-based alloys showed a similar trend to the Ni and 1045 steel alloys. The CP-Ti alloys show a number of cycles to failure being ˜18,000 and transitioned at CoF of 0.58 on average. For the treated Ti-6Al-4V, the stabilized CoF was ˜0.098 and was sustained for ˜20,000 cycles. After the deterioration of the carbon coatings, there was a transition from the low CoF to a high value of 0.57 on average. The reduction of the CoF of the treated metallic substrates was on average 95.8% for Ni Invar, 94.8%, for 1045 steel, 70.7% for Ti-6Al-4V and 68.9% for CP-Ti. This overall reduction is due to the graphitic protection that enhanced carbon-carbon interactions on the coated surfaces. The number of cycles to failure is enough to ensure that catastrophic failures are prohibited for most standard applications with less aggressive abrasive and adhesive wear. The extended number of cycles to failure on the Ni-Invar and the steel alloys also leads to a prolonged lifecycle for materials used in high friction and wear applications.

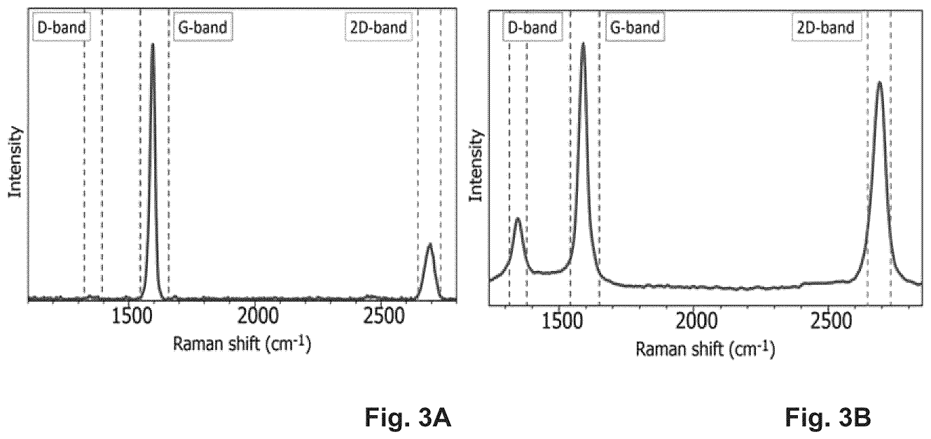

Returning to FIG. 1, and continuing to refer to FIGS. 2-3, formation of the superlubricity coating involves HTBT using a suitable biowaste source. The disclosed method for forming superlubricity coating includes generating a granular biowaste medium from agitation of a biowaste source. In the example configuration, the biowaste is sourced from the Casava leaves, which have favorable nitrogen-affinity characteristics and also provide beneficial cyanide. These were dried, milled, and sieved to powder with an average particle size of ˜200 μm. The preferable size range for the granulated casava leaves results in a particle size of between 250-300 μm.

The powder was then mixed with of BaCO₃ in a ratio of 3:1. The BaCO₃ is used as an activation compound for the carbon nanocrystal deposition. Other suitable activation agents or compounds may be combined with the granular biowaste medium; the activation agent may be selected for introducing nitrogen or otherwise favoring nitrogen reactions.

Using a suitable high temperature containment 110, the granular biowaste medium surrounds the metallic component 150′ for providing a carbon source. The metallic component is placed in the containment 110 and the granular biowaste medium and activation agent mixture, now having a powder consistency, surrounds the metallic component 150′ so that all surfaces are generally covered or in contact with the powder.

The furnace or other heat source 120 heats the containment 110 with the metallic component in the biowaste medium for diffusing carbon from the biowaste medium to aggregate on a surface of the component, thereby forming a graphene coating or similar carbon crystal, superlubricity coating. Heating the containment may occur at a temperature between 800° C.-1100° C., or certain applications may employ a lower temperature range between 500° C.-800° C. A typical heating duration is between 3-5 hours. Both temperature and time may be varied depending on the composition or shape of the substrate 150. Typical substrates may include steel balls, engine pistons or moving components, bearings and any metal or alloy surface engaging in frictional communication with an opposed surface for rotational or slidable interaction.

The resulting coating, as described in FIG. 2, may take the form of various carbon crystals or graphene structures. For example, the carbon coating may be defined by a nanofiber mesh of nano tubes with an average diameter of ˜30±12 nm. Both carbon nanotubes and carbon nanocrystals form low friction surfaces; technical definitions may define graphene to be a single molecule thickness, with 10 or more such layers then forming a graphite coating. Whatever the aggregation and/or accumulation of carbon diffused out of the biowaste onto the substrate 150, a superlubricity or similar carbon-based coating is deposited for favorable friction results. The activation agent (barium carbonate), cyanide and other substance which favor the production of nitrogen for facilitating carbon diffusion are all beneficial.

In a particular use case, a metallic crucible (mild steel cylinder) defines a containment 110 that has an inner diameter of 77.4 mm and an outer diameter of 80.2 mm and a height of 200.3 mm was made for the HTBT. The cylinder was filled with 622 g of processed biowaste powder plus a BaCO₃ mixture. Three metallic samples were treated at a time at 900° C. 100Cr steel balls and AISI 1045 steel samples were treated for 3 h. The CP Ti, Ti-6Al-4V, Ni-Invar and another batch of AISI 1045 steel samples were treated for 5 hours. The cylinder was sealed with high-temperature cement at all exposed joints. The specimens were air-cooled after the treatment. The morphology and deposition stages of the carbon coating were studied within 1 hour time intervals.

Raman Spectroscopy was used to characterize the carbon nanocrystals on the surfaces of the heat treated substrates, which was also used to characterize the wear tracks within different time intervals. AFM (Atomic Force Microscopy) experiments were performed on the surfaces of the substrates after the HTBT treatments. AFM is a type of scanning probe microscopy (SPM), with demonstrated resolution on the order of fractions of a nanometer.

FIG. 3 shows reference Raman shift spectra for identifying graphene coatings on metal articles, In Raman specta, referring to FIGS. 3A and 3B, peaks in the G band and 2D band indicate a graphene presence. A D band peak may indicate a defect or impurity in the graphene coating.

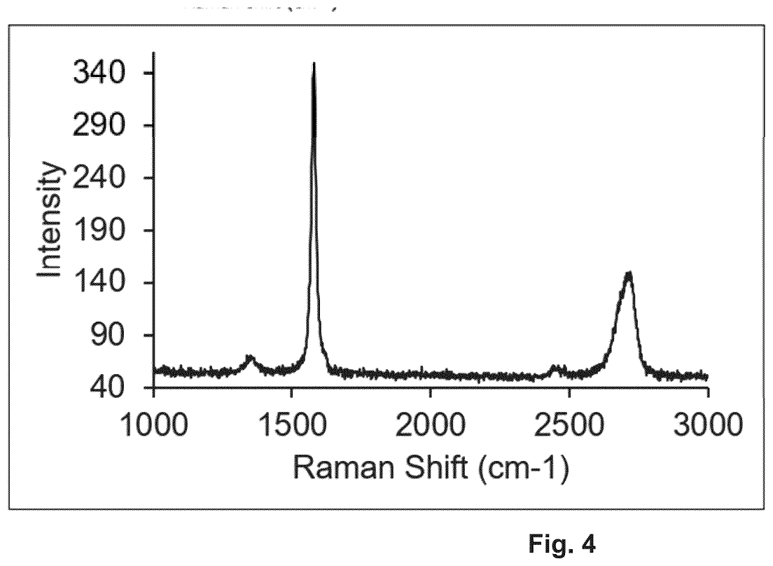

FIG. 4 shows a Raman shift spectra for an example alloy. In FIG. 4, a 400 Monel 4 h sample was treated at 1093° C., and exhibits the G-band and 2D band peaks consistent with graphene, and only a modest peak in the defect-indicating D-band. Monel is an alloy including nickel and copper.

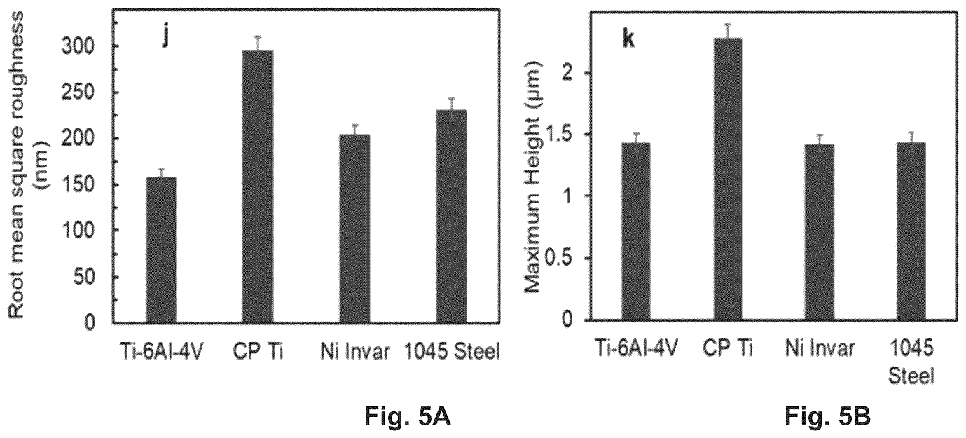

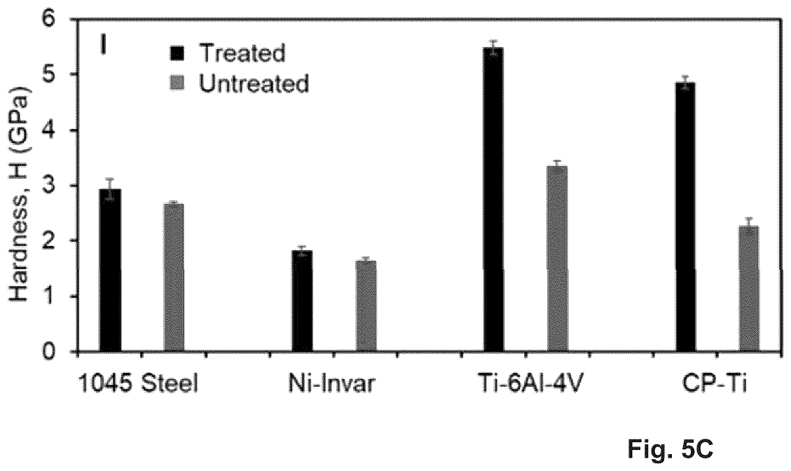

FIGS. 5A-5C show surface roughness for the applied graphene coating. Referring to FIGS. 5A-5C, FIG. 5A shows RMS roughness for the surfaces of the treated substrates, and FIG. 5B shows the maximum deposited height of carbon nanocrystal coating on substrates. FIG. 5C contrasts hardness values under treated and untreated conditions. Conventional approaches to biowaste based heat treatment seek surface hardening, so an apparent correlation between surface hardness and superlubricity may be expected.

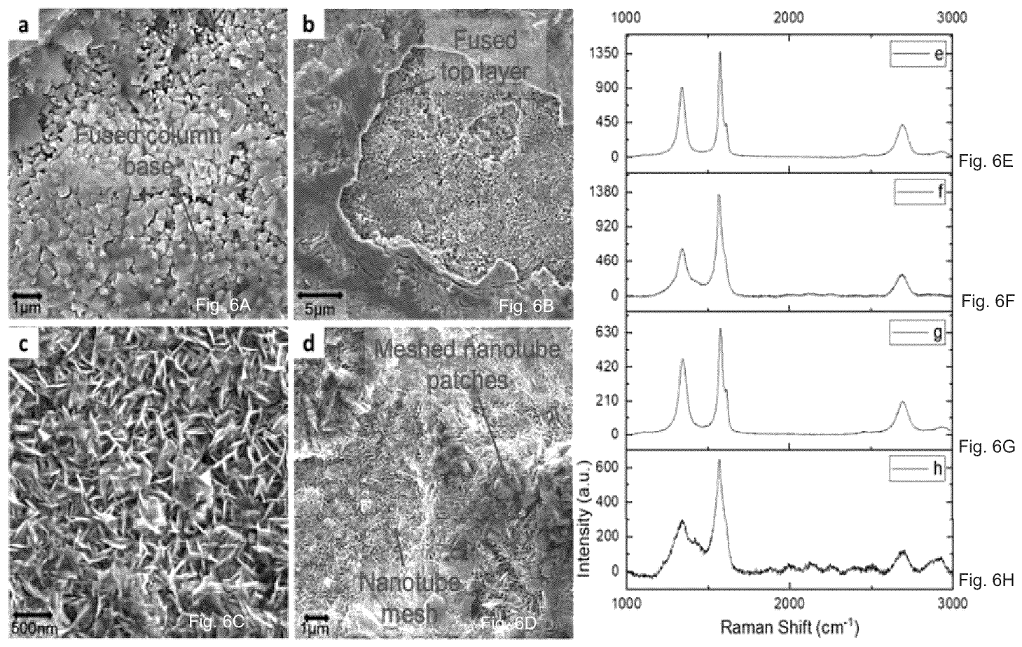

FIGS. 6A-6D show SEM images of the superlubricity coating as applied to Ni-Invar substrates. Invar is an alloy of iron and about one third nickel that expands very little when heated. SEM images of the Ni-Invar substrates with the various Raman spectra are given in FIGS. 6A-6H. This layer formed ridges and patches that covered most of the substrate surface. Vertically oriented crystals were observed to nucleate from the substrate. FIG. 6A shows that these created the base structure of the carbon coating showing columns of carbon nanocrystal precipitates. FIG. 6B shows fused column layer and the plate-like top coating. In FIG. 6C, a high magnification of top carbon nanotube meshed coating is shown. The top layer was made up of nanofiber mesh of nano tubes with an average diameter of ˜30±12 nm. FIG. 6D depicts irregular top carbon nanotube meshed coatings with the Raman spectra. The Raman spectra of the carbon coatings of FIGS. 6E-6H exhibit D bands at 1350 cm⁻¹, G bands at 1570 cm⁻¹ and 2D bands at 2700 cm⁻¹ positions. The intensity ratio I_{D}/I_{G} was 0.88 and the I_{2D}/I_{G} was 0.74. Various doping and substrate composition can affect the Raman shift graph away from the ideal G band and 2D bands of FIG. 3A-3B.

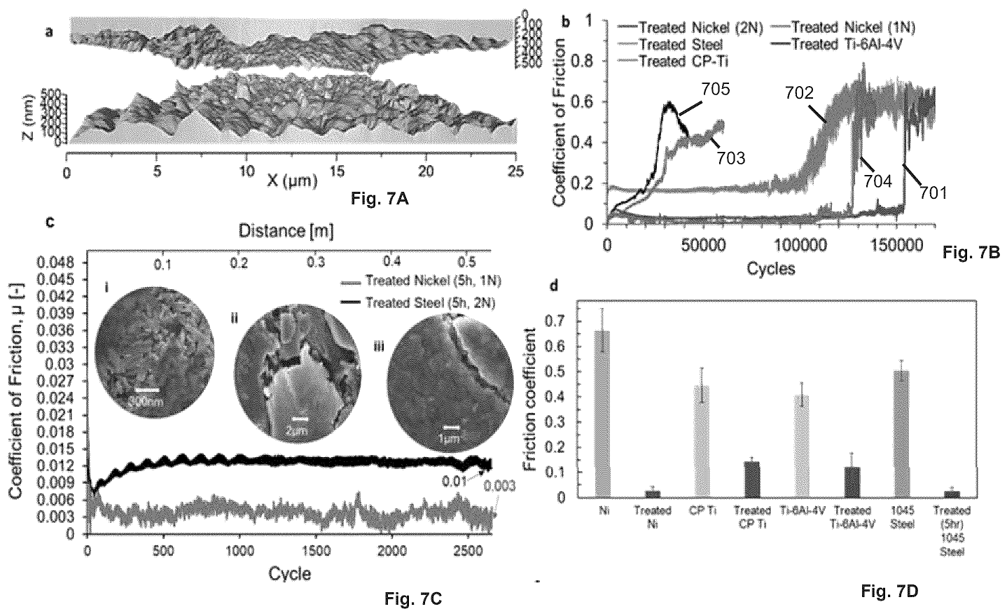

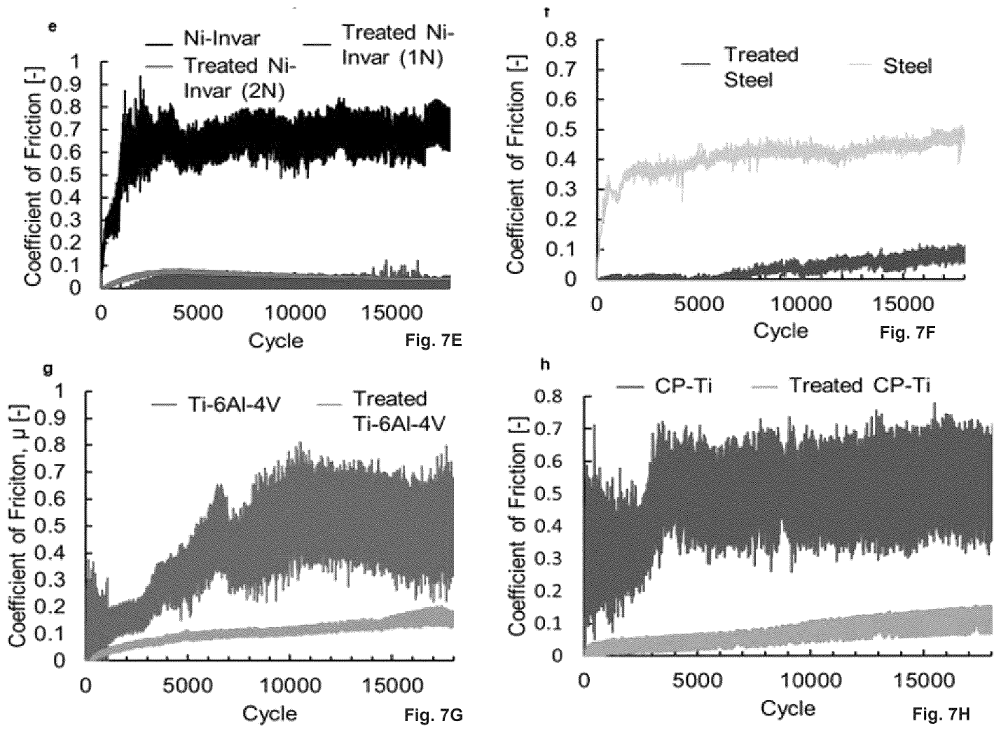

FIGS. 7A-7H depict surface features and graphs of Coefficient of Friction (CoF) attributes of the superlubricity coating in the form of friction coefficient plots obtained from the untreated and treated metallic substrates. Typical topographic images of the mating surfaces obtained using non-contact mode AFM are demonstrated in FIG. 7A. These are incommensurable surfaces with apparent multiple nano- and microcontact points. FIG. 7B shows ultra-low friction results for the sliding test on the treated 1045 steel and Ni-Invar substrates. The graph lines depict the coefficient of friction variance over contact cycles for treated Ni (2N load) 701, treated steel 702, treated CP-Ti, treated Ni (1N load) 704 and treated Ti-6AI-4V. The three main transition zones of friction coefficients and associated microstructural characterization of the graphitic coating are shown in the inset photographic insets of FIG. 7C. Referring to FIG. 7C, the initial state was associated with low friction coefficients from 0 to ˜1000 cycles before a transition to ultra-low CoF values up to ˜0.003 and ˜0.01 (for cycles above 1000 for the treated Ni-Invar (lower graphed line) and 1045 steel substrates (upper line). The initial low CoF phase was associated with preliminary multiple microcontact interactions between the walls of the carbon nanocrystals on the contacting surfaces. The SEM image of the carbon nanocrystals on the wear tracks is presented in the leftmost inset. The irregularly deformed surfaces reveal evidence of flattening carbon nanocrystals with a range of orientations.

Continuous load bearing and sliding action led to the deformation, coalescence, and fusion of carbon nanocrystals into graphene composite flakes in the middle inset of FIG. 7C. These flakes subsequently coalesced into graphene nanocomposite films (GNCF) that intercalated between the treated 100Cr steel ball and the treated substrates, as shown in the rightmost inset. The corrugated graphitic films (on the ball and substrate) separating the contacting surfaces at the micron and submicron scales provide the conditions required for sustained macroscale superlubricity. The ultra-low friction regimes are associated with the flattening of corrugated surfaces as shown in the FIG. 7C insets, which results in decreasing friction force as the normal force increases. The root mean square roughness values of the nano- and microcontact points on the 1000 cycles wear tracks of the treated samples were 65±8.03 nm, 129.59±27.31 nm, 122.1±34.22 nm and 128.6÷40.12 nm for Ti-6Al-4V, CP Ti, Ni-Invar and 1045 steel, respectively. These roughness values were lower than those observed before the wear tests were conducted, due to the flattening and formation of the graphene nanocomposite films in the wear tracks.

Returning to FIG. 7B, the evolution of CoFs for the treated substrates is shown. The CoFs increased from plunging states at the beginning of the test to stable mean values. On average, these were sustained for several cycles (depending on the material) before transitioning to high friction coefficients. These trends indicate of a change in the friction mechanisms and the end of the graphitic protection. After the initial plunging, the CoF for the treated Ni-Invar at 1 N load was stabilized at a mean value of ˜0.007 and maintained for ˜120,000 number of cycles to failure with a corresponding CoF of 0.5. However, at 2 N, the mean stabilized CoF was at ˜0.027 and was sustained for ˜150,000 cycles to failure before transitioning to a mean CoF of 0.58. For the 5 N load at 500 rpm, a high CoF of 0.29 on average was observed in the stabilized regime. The corresponding number of cycles to failure sustained was ˜70,000 cycles before transitioning to a higher CoF value. The stabilized CoF obtained for the treated 1045 steel (treated for 3 hrs) was 0.15 on average. This value was sustained for ˜100,000 cycles, with an average final transitioned CoF value of 0.6.

FIG. 7D shows friction coefficients for the treated and untreated metallic substrates. This contrasts the Coefficient of Friction versus number of cycles plots in the stabilized regimes of treated substrates (tests done with treated 100Cr steel balls), as compared to untreated substrates (done with untreated 100Cr Steel ball) of Ni-Invar FIG. 7E); Ti-6Al-4V (FIG. 7F) 1045 steel (FIG. 7G); and CP Ti in FIG. 7H.

The CoF of the treated Ti-based alloys showed a similar trend to the Ni and 1045 steel alloys. The CP—Ti alloys were stabilized at ˜0.12 with corresponding number of cycles to failure being ˜18,000 and transitioned at CoF of 0.58 on average. For the treated Ti-6Al-4V, the stabilized CoF was ˜0.098 and sustained for ˜20,000 cycles. After the deterioration of the carbon coatings, there was a transition from the low CoF to a high value of 0.57 on average. The extent of CoF reduction for the treated and untreated substrates in the stabilized regime is shown in FIGS. 7E-7H. The reduction of the CoF of the treated metallic substrates was on average 95.8% for Ni Invar, 94.8%, for 1045 steel, 70.7% for Ti-6Al-4V and 68.9% for CP-Ti, as shown in FIG. 7D. This overall reduction is due to the graphitic protection that enhanced carbon-carbon interactions on the coated surfaces. Although, the CoF and the number of cycles to failure of the carbon-coated CP-Ti substrate was lowest, it was higher than data for some alloys. The number of cycles to failure is enough to ensure that catastrophic failures are prohibited for most standard applications with less aggressive abrasive and adhesive wear. The extended number of cycles to failure on the Ni-Invar and the steel alloys would also lead to a prolonged lifecycle for materials used in high friction and wear applications.

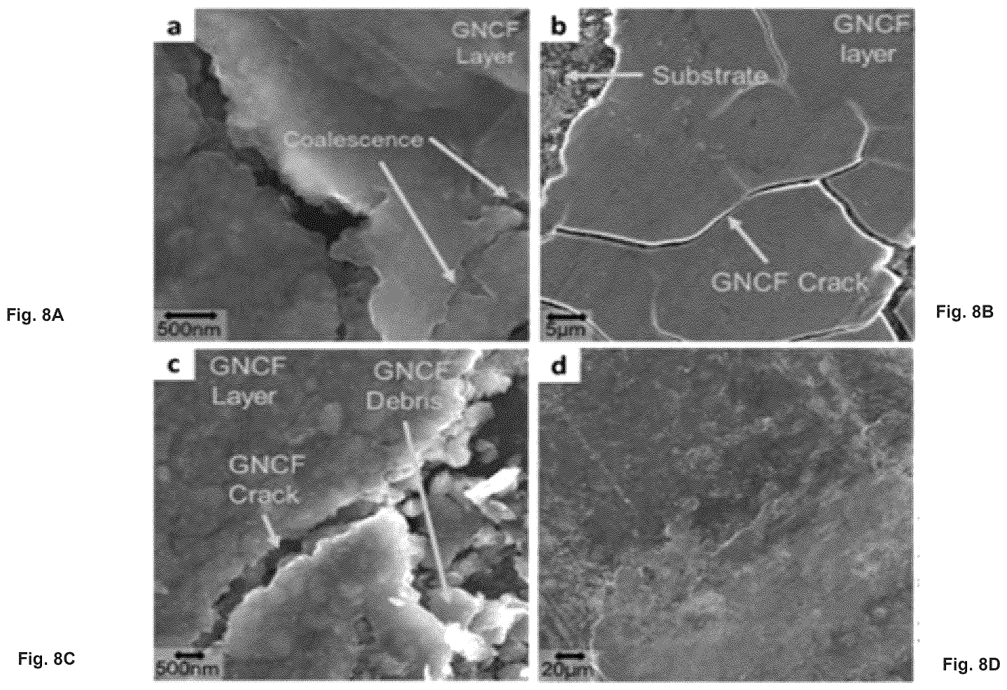

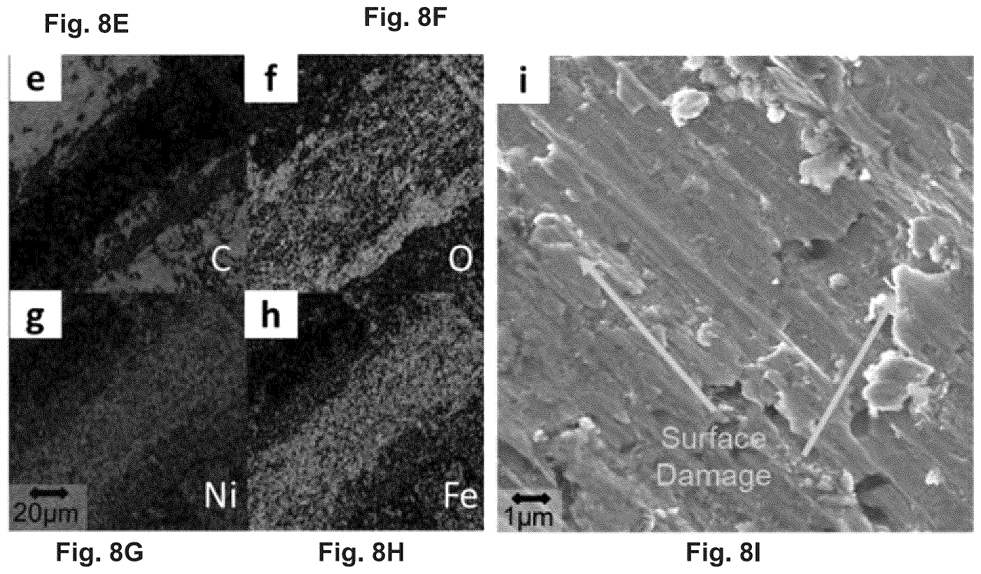

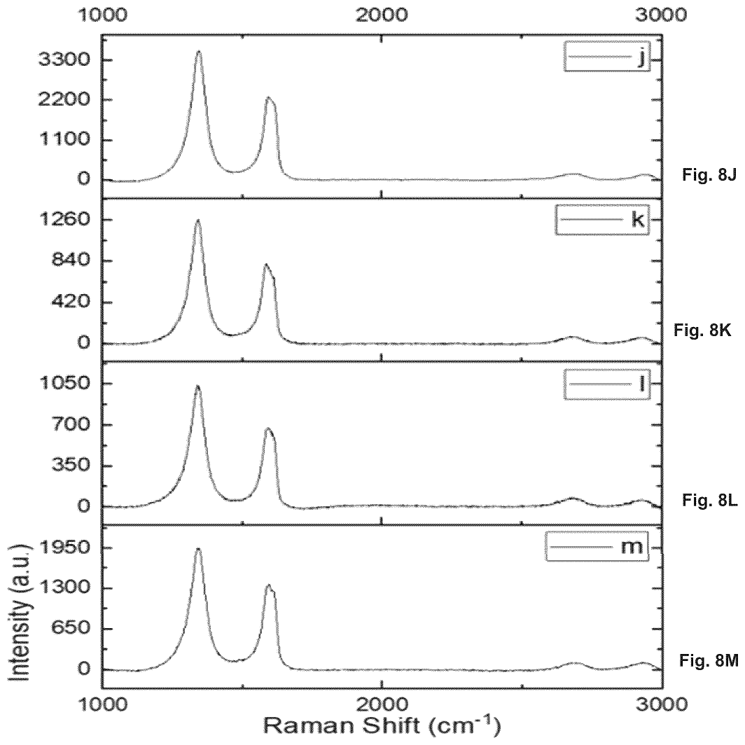

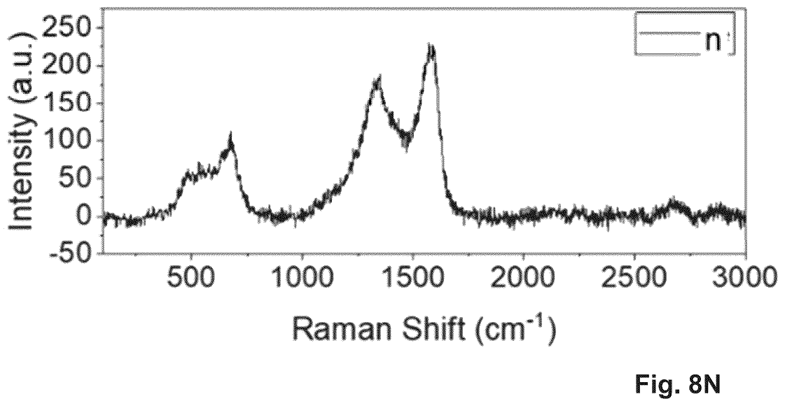

Additional tests depict the wear of carbon nanocrystal coating on metallic Substrates. FIGS. 8A-8N show SEM images and Raman graphs of the graphene in the superlubricity coating. Collectively, the wear experiments on the carbon-coated and uncoated metallic surfaces revealed different wear rates and coating life. These wear behaviour and coating lives are generally dependent on the deformation, cracking, and removal of the GNCFs. The GNCFs were formed and sustained in the wear tracks for different cycles to failure and time durations. The extent of the carbon coating and associated protection controlled the mechanisms of wear on the treated substrates.

FIGS. 8A-D show SEM images of graphene nanocomposite film on 30 min wear track of Ni-Invar. Referring to FIGS. 8A-8D, the SEM images of the wear tracks on the Ni-Invar, as characterised from 3 min to 2 h during wear, reveal the presence of the graphene nanocomposite film in the wear tracks. The film forms under the dynamic contact conditions associated with the sliding of the treated ball on the carbon nanocrystals in the coating, while the GNCF forms on both the ball's surface and the substrate. Cracks and wear debris of the GNCF are observed in the wear tracks, as the number of cycles increases. The GNCF was removed from the wear tracks after ˜150,000 cycles of the experiment with a 2 N load. The wear rate of the coated structure was also reduced by ˜86% as compared to the untreated substrates.

FIGS. 8E-8H show EDS (Energy Dispersive Spectroscopy) results of 30 min wear track of treated Ni Invar, indicating the presence of Fe, C, O and Ni respectively in the wear tracks. The EDS analyses show substrate elements such as Ni and Fe mixed into the GNCF. The EDS also detected oxygen combining with carbon and the substrate elements to form tribological oxidated products.

FIG. 8I shows SEM image of wear track in the untreated Ni-Invar substrate after 30 mins of wear. In FIG. 8I, an SEM image of a wear track in the untreated Ni-Invar substrate, after 30 min of wear with an untreated 100Cr steel ball. Abrasive wear with surface damage dominates the wear tracks with traces of adhesion wear leading to higher wear rates in the untreated material than in treated ones. No evidence of these two mechanisms was observed on the surfaces of the treated substrates, when the GNCF covered most of the wear tracks, thus prolonging the wear live/cycles to failure.

FIGS. 8J-8M show Raman spectra of the composite film in the wear track, indicating the presence of graphene nanocrystals. In FIGS. 8J-8M, The Raman spectra of the GNCF had D at 1346 cm⁻¹, G at 1597 cm⁻¹ and 2D bands at 2700 cm⁻¹. The intensity ratio IDAG was 1.27, whereas that of I_{2D/G} was 0.5. This Raman signature is synonymous with graphene nanocrystal films from chemical exfoliation, and those on wear tracks of diamond-like carbon surfaces. The graphene nanocrystal films were dominant in the Raman scatter results. However, there were distortions in the initial Raman peaks for the carbon coating on the substrates. This confirms the occurrence of tribologically induced graphitization. The graphitization of the coating layers occurs due to high stresses and temperatures under the counter body, distorting the carbon structure.

FIG. 8N shows Raman spectra of 30 min wear track of untreated Ni-Invar showing Nickel oxide peaks. The Raman spectra of the debris on the wear tracks on the untreated material in FIG. 8N reveals the presence of NiO and Fe₂O₃ peaks, which resulted from the adhesion wear interactions of tribological oxidation products.

The disclosed configurations above demonstrate a simple and inexpensive approach to coatings providing macroscale metallic superlubricity using the disclosed high temperature biowaste treatment method with Manihot esculenta, or Casava leaves, as the carbon source.

In sum, the disclosed approach provides macroscale superlubricity was attained with coefficients of ˜0.007 and was sustained for more than 150000 cycles before failure. This sets a new milestone for graphitic coatings for wear and friction applications. The primary mechanism for the superlubricious behaviour exhibited by the disclosed approach is the many microcontacts points inducing ultralow friction behaviour.

While the system and methods defined herein have been particularly shown and described with references to embodiments thereof, it will be understood by those skilled in the art that various changes in form and details may be made therein without departing from the scope of the invention encompassed by the appended claims.

What is claimed is:

1. A method for forming superlubricity coating, comprising:
generating a granular biowaste medium from a high temperature biowaste treatment (HTBT), the granular biowaste medium;
surrounding the metallic component with the granular biowaste medium for providing a carbon source; and
heating the metallic component in the biowaste medium for diffusing carbon from the biowaste medium to aggregate on a surface of the component thereby forming a graphene coating.

2. The method of claim 1 further comprising combining an activation agent with the granular biowaste medium, the activation agent selected for introducing nitrogen.

3. The method of claim 2 wherein the activation agent is BaCO₃.

4. The method of claim 1 wherein the graphene coating includes carbon nanotubes.

5. The method of claim 1 wherein the graphene coating includes carbon nanocrystals.

6. The method of claim 1 wherein the biowaste medium includes cyanide.

7. The method of claim 1 further comprising grinding the biowaste medium to a particle size of 250-300 μm.

8. The method of claim 1 wherein the biowaste medium includes granulated casava leaves having a particle size of 250-300 μm.

9. The method of claim 3 wherein the biowaste medium includes barium carbonate in about a 3:1 ratio.

10. The method of claim 1 further comprising:
depositing the metallic component in a containment;
covering the metallic component with heating the metallic component with the granular biowaste medium for surrounding the metallic component with the granular biowaste medium; and
heating the containment at a temperature between 800° C.-1100° C.

11. The method of claim 1 further comprising:
depositing the metallic component in a containment;
covering the metallic component with heating the metallic component with the granular biowaste medium for surrounding the metallic component with the granular biowaste medium; and
heating the containment at a temperature between 500° C.-800° C.

12. The method of claim 1 further comprising heating the metallic component in the biowaste medium for between 3-5 hours.

13. The method of claim 1 wherein the carbon coating includes a nanofiber mesh of nano tubes with an average diameter of ˜30±12 nm.

14. A system for forming a frictionally engaged element with a superlubricity coating, comprising:
a metallic component adapted for frictional engagement via a graphene coating, the graphene coating resulting from a high temperature biowaste treatment (HTBT) including:
a containment for surrounding the metallic component with a granular biowaste medium defining a carbon source; and
a furnace for heating the containment with the metallic component in the biowaste medium for diffusing carbon from the biowaste medium to aggregate on a surface of the component thereby forming the graphene coating.

15. The system of claim 14 further comprising an activation agent combined with the granular biowaste medium, the activation agent selected for introducing nitrogen.

16. The system of claim 15 wherein the activation agent is BaCO₃.

17. The system of claim 14 wherein the graphene coating includes carbon nanotubes.

18. The system of claim 14 further comprising a grinder for granulating the biowaste medium to a particle size of 250-300 μm.

19. The system of claim 14 wherein the furnace heats the containment to a temperature between 800° C.-1100° C.

20. The system of claim 14 wherein the containment is heated for a duration between 3 and 5 hours.

21. The system of claim 14 where the graphene coating performs with an initial CoF (Coefficient of Friction) less than 0.2 for at least 100,000 frictional contact cycles.

22. The system of claim 14 where the graphene coating achieves a CoF (Coefficient of Friction) less than 0.1 for at least 5000 frictional contact cycles.
